(19) United States
(12) Patent Application Publication
(10) Pub. No.: US 2026/0096269 A1
(43) Pub. Date: Apr. 2, 2026

(54) DISPLAY PANEL AND DISPLAY DEVICE

(71) Applicant: HKC CORPORATION LIMITED, SHENZHEN (CN)

(72) Inventors: Qin LIANG, SHENZHEN (CN); Yangling TANG, SHENZHEN (CN); Zhisheng XIE, SHENZHEN (CN); Xiufeng ZHOU, SHENZHEN (CN); Haijiang YUAN, SHENZHEN (CN)

(73) Assignee: HKC CORPORATION LIMITED, SHENZHEN (CN)

(21) Appl. No.: 19/334,551

(22) Filed: Sep. 19, 2025

(30) Foreign Application Priority Data
Sep. 30, 2024 (CN) 202411391108.8

(51) Int. Cl. H10H 29/49; H10H 20/853; H10H 29/37

(52) U.S. Cl. CPC H10H 29/49; H10H 20/853; H10H 29/37

(57) ABSTRACT

A display panel and a display device are provided. The display panel includes multiple pixel islands, where each pixel island includes at least one sub-pixel; a connection bridge, stretchably connected between adjacent two of the pixel islands; and a protection unit, disposed around a corresponding one of the pixel islands and spaced apart from the corresponding one of the pixel islands, configured to generate a resistance to prevent stretching deformation when the display panel is stretched. The connection bridge includes: a first connection portion, connected to the corresponding one of the pixel islands and the protection unit; and a second connection portion, connected to two adjacent protection units. The protection unit is conductive.

### CROSS REFERENCE TO RELATED APPLICATIONS

The present disclosure claims priority of Chinese Patent Application No. 202411391108.8, filed on Sep. 30, 2024, the entire contents of which are hereby incorporated by reference in their entireties.

### TECHNICAL FIELD

The present disclosure relates to the field of display technologies, and in particular to a display panel and a display device.

### BACKGROUND

A stretchable display panel, as an important technological advancement following foldable displays in flexible display technologies, has an arbitrary directional variability and a stretchable recoverability. The stretchable display panel has broad application prospects, and may be applied to various fields such as consumer electronics, public display, medical, biological, wearable, gaming, fashion, and in-vehicle scenarios, or the like.

An existing stretchable display panel generally includes an island-shaped light-emitting region and a bridge-shaped wiring region, and a deformation capability of the wiring region is generally improved by designing curved wire/line. However, due to defects in the above structural design, the twisting deformation in the wiring region may further cause the twisting deformation in the island-shaped light-emitting region, result in reducing the reliability of a pixel unit in the island-shaped display region and a poor display effect.

### SUMMARY OF THE DISCLOSURE

According to a first aspect, some embodiments of the present disclosure provide a display panel. The display panel includes a plurality of pixel islands, each pixel island including at least one sub-pixel; and a connection bridge, stretchably connected between adjacent two of the pixel islands. The display panel further includes a protection unit disposed around a corresponding one of the pixel islands, and the protection unit is spaced apart from the corresponding one of the pixel islands. The protection unit is configured to generate a resistance to prevent stretching deformation in a case where the display panel is stretched. The connection bridge includes a first connection portion and a second connection portion, the first connection portion is connected to the corresponding one of the pixel islands and the protection unit, the second connection portion is connected to two adjacent protection units, and the protection unit is conductive.

According to a second aspect, some embodiments of the present disclosure provide a display device. The display device includes the display panel according to the above-mentioned embodiment; and a control circuit board, electrically connected to the display panel and configured to control the display panel to display a corresponding image.

### BRIEF DESCRIPTION OF THE DRAWINGS

In order to more clearly describe the technical solutions in the embodiments of the present disclosure, the following will briefly introduce the drawings required in the description of the embodiments. Obviously, the drawings in the following description are only some embodiments of the present disclosure. For those skilled in the art, other drawings may be obtained based on these drawings without creative work.

FIG. 1 is a schematic view of a planar structure of a display panel according to some embodiments of the present disclosure.

FIG. 2 is a schematic view of a planar structure of a display panel according to some embodiments of the present disclosure.

FIG. 3 is a schematic view of a planar structure of a display panel according to some embodiments of the present disclosure.

FIG. 4 is a schematic view of a planar structure of a display panel according to some embodiments of the present disclosure.

FIG. 5 is a cross-sectional structural schematic view of a display panel along a direction of line A-A in FIG. 4 according to some embodiments of the present disclosure.

FIG. 6 is a cross-sectional structural schematic view of a display panel along a direction of line B-B in FIG. 4 according to some embodiments of the present disclosure.

FIG. 7 is a cross-sectional structural schematic view of a display panel along a direction of line C-C in FIG. 4 according to some embodiments of the present disclosure.

FIG. 8 is a cross-sectional structural schematic view of a display panel along a direction of line A-A in FIG. 4 according to another embodiment of the present disclosure.

FIG. 9 is a structural schematic diagram of a display device according to some embodiments of the present disclosure.

### DETAILED DESCRIPTION

The technical solutions of the embodiments of the present disclosure will be described in detail below in conjunction with the accompanying drawings.

In the following description, for purposes of illustration rather than limitation, specific details, such as specific system architectures, interfaces, and techniques, are set forth in order to provide a thorough understanding of the present disclosure.

The following will clearly and completely describe the technical solutions in the embodiments of the present disclosure in conjunction with the accompanying drawings in the embodiments of the present disclosure. Obviously, the described embodiments are only part of the embodiments of the present disclosure, not all of them. Based on the embodiments of the present disclosure, all other embodiments acquired by those skilled in the art without creative work shall fall within the scope of protection in the present disclosure.

The terms “first”, “second”, and “third” in the present disclosure are used for descriptive purposes only, and cannot be understood as indicating or implying relative importance or implicitly specifying the quantity of indicated technical features. Thus, features defined as “first”, “second”, and “third” may explicitly or implicitly include at least one of these features. In the description of the present disclosure, “a plurality of/multiple” means at least two, such as two, three, etc., unless otherwise specifically defined. All directional indications (such as up, down, left, right, front, back . . . ) in the embodiments of the present disclosure are only used to explain the relative positional relationships, movements, etc., of components in a certain posture (as shown in the figure), and if the specific posture is changed, the directional indications are also changed accordingly. Furthermore, the terms “include”, “have”, and any variations thereof, are intended to cover a non-exclusive inclusion. For example, a process, method, system, product, or device including a series of operations or units is not limited to the listed operations or units, but optionally also includes unlisted operations or units, or optionally further includes other operations or units inherent in the process, method, product, or device.

Reference to “embodiment” in the present disclosure means that, specific features, structures, or characteristics described in conjunction with the embodiments may be included in at least one embodiment of the present disclosure. The presence of the phrase at each location in the specification does not necessarily refer to the same embodiment, nor is it a separate or alternative embodiment that is mutually exclusive with other embodiments. It is understood, both explicitly and implicitly, by those skilled in the art that embodiments described herein may be combined with other embodiments.

The present disclosure may be described in detail below in conjunction with the accompanying drawings and embodiments.

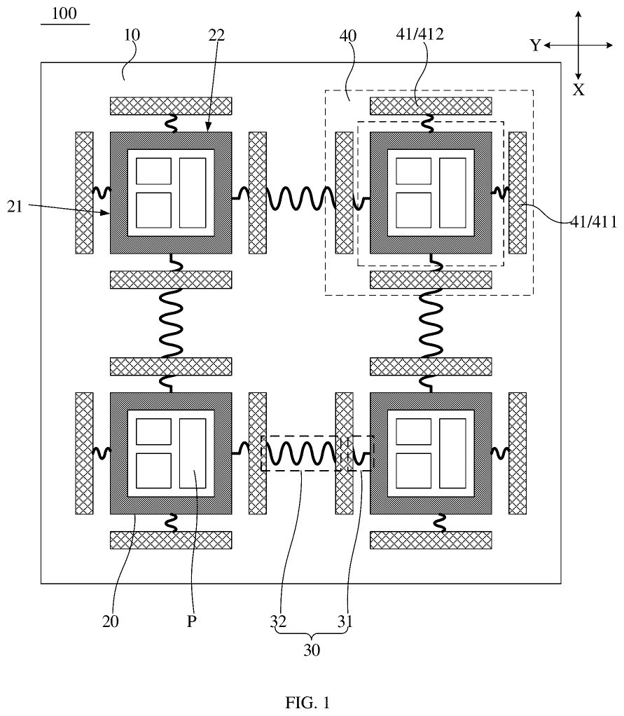

As shown in FIG. 1, FIG. 1 is a schematic view of a planar structure of a display panel according to some embodiments of the present disclosure. The display panel 100 may be provided by some embodiments of the present disclosure. The display panel 100 may include multiple pixel islands 20, a connection bridge 30, and a protection unit 40.

In some embodiments, the multiple pixel islands 20 may be arranged in a matrix and spaced apart from each other. Each pixel island 20 may include at least one sub-pixel P to display an image. The connection bridge 30 may be stretchably connected between adjacent two of the pixel islands 20 to transmit a driving signal. In a case where the display panel 100 is stretched, the connection bridge 30 may be in a stretched state. In some embodiments, the display panel 100 may further include a flexible substrate 10 configured to carry the multiple pixel islands 20 and the connection bridge 30. A material of the flexible substrate 10 may be a material with a flexible bending property, such as polydimethylsiloxane (PDMS), polyimide (PI), etc., such that it may be possible to enable the display panel 100 to have a stretchable performance.

In some embodiments, the display panel 100 may further include a protection unit 40. The protection unit 40 may be disposed around a corresponding one of the pixel islands 20. The protection unit 40 may be spaced apart from the corresponding one of the pixel islands 20. The protection unit 40 may be configured to generate a resistance to prevent stretching deformation in a case where the display panel is stretched. In some embodiments, the connection bridge 30 may include a first connection portion 31 and a second connection portion 32. The first connection portion 31 may be connected to the corresponding one of the pixel islands 20 and the protection unit 40, the second connection portion 32 may be connected to two adjacent protection units 40. The protection unit may be conductive.

In some embodiments, the protection unit 40 may be disposed around the corresponding one of the pixel islands 20, and in a case where the display panel 100 is stretched and deformed, the protection unit may be configured to generate a resistance opposite to a direction of a stretching deformation stress, such that it may be possible to have a function of preventing the stretching deformation in a stretching direction. That is, by an anti-deformation capability of the protection unit, it may be possible to effectively reduce the influence of the stress generated by the stretching deformation on the corresponding one of the pixel islands 20, such that it may be possible to prevent the corresponding one of the pixel islands 20 from being damaged by the deformation stress, thereby improving the anti-deformation capability of the pixel islands 20.

In some embodiments, the protection unit 40 may be spaced apart from the corresponding one of the pixel islands 20. That is, a spacing/gap with a preset width may be provided between the protection unit 40 and the corresponding one of the pixel islands 20. The connection bridge 30 may include the first connection portion 31 and the second connection portion 32. An end of the first connection portion 31 may be connected to an outer side of the corresponding one of the pixel islands 20, and another end of the first connection portion 31 may be connected to a side of the protection unit 40 close to the corresponding one of the pixel islands 20. An end of the second connection portion 32 may be connected to a side of one of the two adjacent protection units 40 opposite to the corresponding one of the pixel islands 20, and another end of the second connection portion 32 may be connected to a side of another one of the two adjacent protection units 40 opposite to another corresponding one of the pixel islands 20. It may be understood that a same second connection portion 32 may be shared between adjacent protection units 40. That is, the second connection portion 32 disposed between two adjacent protection units 40 may be the same second connection portion 32. Alternatively, it may be understood that adjacent two of the pixel islands 20 may be respectively a pixel island A and a pixel island B. The connection bridge 30, which is disposed between a side of the pixel island A and a side of the pixel island B close to the side of the pixel island A, may include two first connection portions 31 and one second connection portion 32. One of the two first connection portions 31 may be connected to the pixel island A and the protection unit 40 corresponding to the one of the two first connection portions 31. The other one of the two first connection portions 31 may be connected to the pixel island B and the protection unit 40 corresponding to the other one of the two first connection portions 31. The second connection portion 32 may be connected to the protection unit 40 corresponding to the pixel island A and the protection unit 40 corresponding to the pixel island B. The protection unit 40 may be conductive, such that it may be possible to implement the connection between the multiple pixel islands 20 to perform stretching and signal transmission.

The protection unit 40 may be spaced apart from the corresponding one of the pixel islands 20, the first connection portion 31 of the connection bridge 30 may be connected to the corresponding one of the pixel islands 20 and the protection unit 40, and the second connection portion 32 may be connected to the protection unit 40 and the adjacent protection unit 40. In this way, in a case where the display panel 100 is stretched and deformed, it may be possible to protect the corresponding one of the pixel islands 20 to maintain/remain structural integrity under an external stretching force, and it may also be possible to ensure good stretchability between the corresponding one of the pixel islands 20 and the protection unit 40 disposed in a periphery of the pixel islands 20, such that it may be possible to enable the display panel 100 to maintain good deformation capability. That is, the first connection portion 31 may be connected between the corresponding one of the pixel islands 20 and the protection unit 40 disposed in the periphery of the pixel islands 20, such that the corresponding one of the pixel islands 20 and the protection unit 40 may have the same stretchable performance. In this way, it may be possible to reduce an occurrence that the stretchable performance of the display panel 100 may be reduced due to a case where the protection unit 40 disposed around the corresponding one of the pixel islands 20, so as to enable the display panel 100 to still maintain the good stretchable performance.

In the embodiments of the present disclosure, a shape of the corresponding one of the pixel islands 20 may be rectangular, square, rhombic, polygonal, or a shape with a curved side. The display panel 100 at least includes a first stretching direction X and a second stretching direction Y intersecting each other. In the embodiments of the present disclosure, the shape of the corresponding one of the pixel islands 20 being rectangular and the multiple pixel islands 20 arranged in a matrix of multiple rows and multiple columns may be exemplarily described as follow. In some embodiments, a column direction of the matrix may be the first stretching direction X, and a row direction of the matrix may be the second stretching direction Y. Two opposite sides of the corresponding one of the pixel islands 20 may be parallel to the first stretching direction X, and the other two opposite sides of the corresponding one of the pixel islands 20 may be parallel to the second stretching direction Y.

In some embodiments, the protection unit 40 may be disconnected at a position corresponding to a corner of the corresponding one of the pixel islands 20, such that multiple protection structures 41 may be formed by the protection unit 40. The corner of the corresponding one of the pixel islands 20 may be referred to a top corner of an edge of the corresponding one of the pixel islands 20, that is, an angle may be formed between adjacent sides of the corresponding one of the pixel islands 20. It may be understood that the multiple protection structures 41 and sides of the corresponding one of the pixel islands 20 may be arranged in one-to-one correspondence. Each side of the corresponding one of the pixel islands 20 may have one protection structure 41 opposite thereto. The connection bridge 30 may be arranged on a periphery of the corresponding one of the pixel islands 20 in each stretching direction, so as to connect a corresponding one of the pixel islands 20 adjacent to the connection bridge 30, and thus it may be possible to form an integral stretchable display structure via the multiple pixel islands 20.

The protection unit 40 may be disconnected at the position corresponding to the corner of the corresponding one of the pixel islands 20, such that multiple strip-shaped protection structures 41 may be formed by the protection unit 40. That is, the one of the protection structures 41 may be corresponding to each side of the corresponding one of the pixel islands 20, and adjacent two of the protection structures 41 may be neither connected nor intersected. Therefore, it may be possible to enable the protection unit 40 to protect the corresponding one of the pixel islands 20 to maintain the structural integrity under external stretching force, and enable the protection unit 40 to have good deformability.

In some embodiments, the protection unit 40 may include a first protection structure 411 extending along the first stretching direction X and a second protection structure 412 extending along the second stretching direction Y. In four sides of the corresponding one of the pixel islands 20, two sides extending along the first stretching direction X may be first sides 21, and other two sides extending along the second stretching direction Y may be second sides 22.

By disconnecting the adjacent two of the protection structures 41, the first protection structure 411 and a corresponding one of first sides 21 of the corresponding one of the pixel islands 20 may maintain good stretchable performance through the corresponding first connection portion 31, such that it may be possible to support stretching, compression, or rotational deformation between the corresponding one of the pixel islands 20 and the protection unit 40 disposed in the periphery of the pixel islands 20. At the same time, in a case where the corresponding one of the pixel islands 20 may be stretched, compressed, or bent in the first stretching direction X, the first protection structure 411 may be configured to generate a resistance opposite to the first stretching direction X, such that it may be possible to enhance an anti-deformation capability of the first protection structure 411, thereby protecting the corresponding one of the pixel islands 20 from structural damage when subjected to a force in the first stretching direction X.

By disconnecting the adjacent two of the protection structures 41, the second protection structure 412 and a corresponding one of second sides 22 of the corresponding one of the pixel islands 20 may maintain good stretchable performance through the corresponding first connection portion 31, such that it may be possible to support stretching, compression, or rotational deformation between the corresponding one of the pixel islands 20 and the protection unit 40 disposed in the periphery of the pixel islands 20. At the same time, in a case where the corresponding one of the pixel islands 20 may be stretched, compressed, or bent in the second stretching direction Y, the second protection structure 412 may be configured to generate a resistance opposite to the second stretching direction Y, such that it may be possible to enhance an anti-deformation capability of the second protection structure 412, thereby protecting the corresponding one of the pixel islands 20 from structural damage when subjected to a force in the second stretching direction Y.

In some embodiments, a corresponding one of the protection structures 41 may be parallel to a side of the corresponding one of the pixel islands 20, and a length of an orthographic projection of the corresponding one of the protection structures on the side of the corresponding one of the pixel islands 20 may be less than a length of the side of the corresponding one of the pixel islands 20. In some embodiments, the first protection structure 411 may be parallel to the corresponding one of first sides 21. A projection of the first protection structure 411 on the corresponding one of first sides 21 does not exceed the corresponding one of first sides 21, that is, the projection of the first protection structure 411 on the corresponding one of first sides 21 may fall within a region of the corresponding one of first sides 21. Similarly, the second protection structure 412 may be parallel to the corresponding one of second sides 22. A projection of the second protection structure 412 on the corresponding one of second sides 22 does not exceed the corresponding one of second sides 22, that is, the projection of the second protection structure 412 on the corresponding one of second sides 22 may fall within a region of the corresponding one of second sides 22.

With the above arrangement, when stretching is performed between the side of the corresponding one of the pixel islands 20 and the corresponding one of the protection structures 41, it may be possible to improve the uniformity of a stretching stress at a region between the side of the corresponding one of the pixel islands 20 and the corresponding one of the protection structures 41 in an extending direction of the corresponding one of the protection structures 41. Therefore, it may be possible to improve the stretchable performance between the corresponding one of the pixel islands 20 and the protection unit 40, so as to reduce the structural damage caused by uneven stress. Similarly, it may be possible to further improve the uniformity of a stretching stress at a first region and a stretching stress at a second region in an extending direction of the corresponding one of the protection structures 41. The first region may be disposed between a side of one of the adjacent two of multiple pixel islands 20 and a side of the corresponding one of the protection structures 41 facing the side of one of the adjacent two of multiple pixel islands 20. The second region may be disposed between a side of a corresponding one of the protection structures 41 opposite to the one of the adjacent two of multiple pixel islands 20 and a side of another corresponding one of the protection structures 41 opposite to the other one of the adjacent two of multiple pixel islands 20. Therefore, it may be possible to improve the stretchable performance between the adjacent two of multiple pixel islands 20, such that the stretchable performance of the display panel 100 may be improved. In addition, the length of an orthographic projection of the corresponding one of the protection structures 41 on the side of the corresponding one of the pixel islands 20 may be less than the length of the side of the corresponding one of the pixel islands 200, such that it may be possible to reduce a tip cracking of the protection structure 41 or a cracking of other film layers during deformation in a case where the display panel 100 is stretched or bent, so as to protect the protection structure 41 and a film layer from being damaged, where the film layer may be disposed at a region where the protection structure 41 is located.

In other embodiments, the side of the corresponding one of the pixel islands 20 may further include a curved side, and accordingly, the protection structure 41 may include a curved protection structure 41 corresponding to the curved side. Similarly, a projection of the curved protection structure 41 on the corresponding curved side does not exceed the corresponding curved side, that is, the projection of the curved protection structure 41 on the corresponding curved side may fall within a region of the corresponding curved side. The curved protection structure 41 may be parallel to the corresponding curved side, thereby achieving the same technical effects as the above-mentioned embodiments. For details, reference may be made to the above description, which may be not repeated herein.

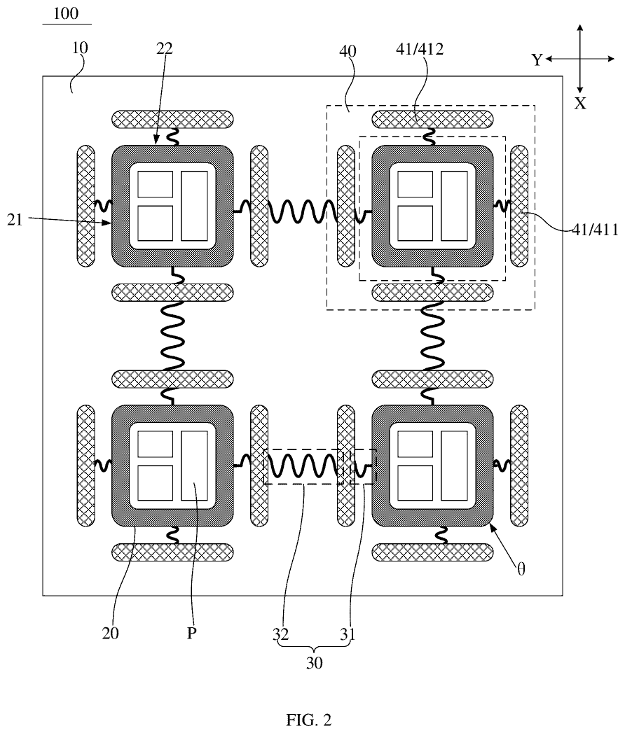

As shown in FIG. 2, FIG. 2 is a schematic view of a planar structure of a display panel according to some embodiments of the present disclosure. In the embodiment of the present disclosure, an angle between adjacent sides of the corresponding one of the pixel islands 20 may be a chamfer θ. That is, an angle between the corresponding one of first sides 21 and the corresponding one of second sides 22 of the corresponding one of the pixel islands 20 may be chamfered to form a linear chamfer θ, a circular chamfer θ, or a composite chamfer θ. The angle between adjacent sides of the corresponding one of the pixel islands 20 is set to the chamfer θ, that is, there may be no sharp corner at an edge corner of the corresponding one of the pixel islands 20, such that it may be possible to further ensure that the corner of the corresponding one of the pixel islands 20 may be not damaged in a case where the display panel 100 is stretched, compressed, bent, or rotated, and at the same time, it may also be possible to reduce the cracking of other film layers caused by the sharp corner.

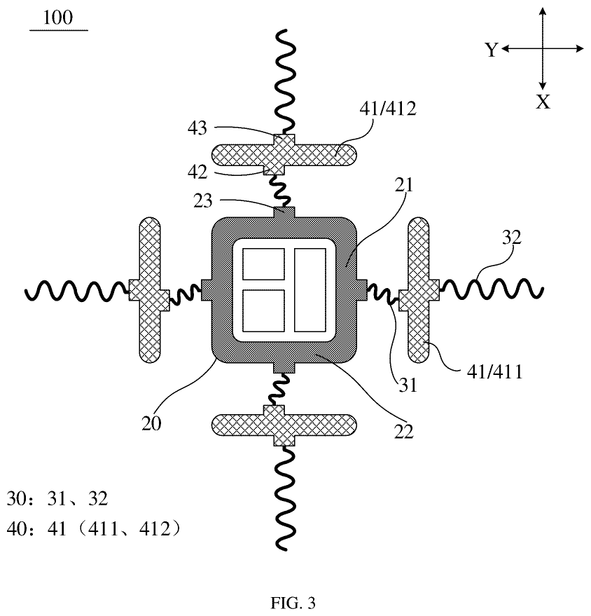

As shown in FIG. 3, FIG. 3 is a schematic view of a planar structure of a display panel according to some embodiments of the present disclosure. In the embodiment of the present disclosure, each side of the corresponding one of the pixel islands 20 may include a first extension portion 23. A side of the corresponding one of the protection structures 41 facing the corresponding one of the pixel islands 20 may include a second extension portion 42. A side of the corresponding one of the protection structures 41 away from the corresponding one of the pixel islands 20 may include a third extension portion 43. The first connection portion 31 may be connected to the corresponding first extension portion 23 and the second extension portion 42. The second connection portion 32 may be connected to two adjacent corresponding third extension portions 43.

That is, an extension portion may be arranged at a connection between the corresponding one of the protection structures 41 and the connection bridge 30. Another extension portion may be further arranged at a connection between the side of the corresponding one of the pixel islands 20 and the connection bridge 30. By arranging the extension portion at the connection between the corresponding one of the protection structures 41 and the connection bridge 30, and the another extension portion at the connection between the side of the corresponding one of the pixel islands 20 and the connection bridge 30, a connection reliability between the connection bridge 30 and the corresponding one of the protection structures 41 may be improved, and a connection reliability between the connection bridge 30 and the corresponding one of the pixel islands 20 may also be improved. In this way, it may be possible to improve firmness of a connection between the connection bridge 30 and the corresponding one of the protection structures 41, and it may be possible to improve firmness of a connection between the connection bridge 30 and the corresponding one of the pixel islands 20. Therefore, in a case where the display panel 100 is stretched, compressed, bent, or rotated, it may be possible to prevent a contact position between the connection bridge 30 and the corresponding one of the protection structures 41 from being damaged, and it may be possible to prevent a contact position between the connection bridge 30 and the corresponding one of the pixel islands 20 from being damaged.

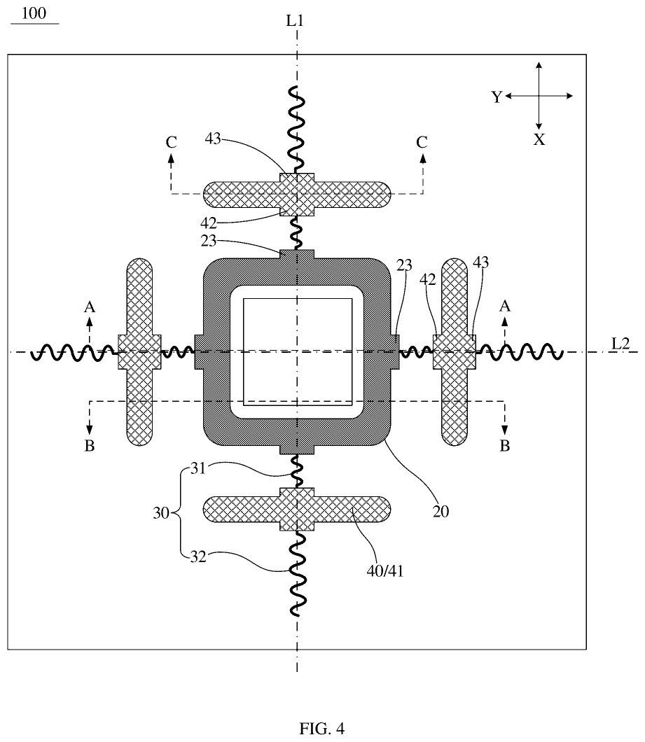

As shown in FIG. 4, FIG. 4 a schematic view of a planar structure of a display panel according to some embodiments of the present disclosure. In some embodiments, the first extension portion 23, the second extension portion 42, and the third extension portion 43 may be arranged along the first stretching direction X and may be disposed on a same first straight line L1. The first straight line L1 may be parallel to the first stretching direction X. The first extension portion 23, the second extension portion 42, and the third extension portion 43 may be arranged along the second stretching direction Y and may be disposed on a same second straight line L2. The second straight line L2 may be parallel to the second stretching direction Y.

It may be understood that the first extension portion 23, the second extension portion 42, and the third extension portion 43 may be arranged along the first stretching direction X and may be disposed on the same first straight line L1, such that a connection position between the second side 22 extending along the second stretching direction Y and the connection bridge 30, i.e., extending along the second stretching direction Y and the first connection portion 31, and a connection position between the second protection structure 412 and the connection bridge 30, i.e., between the second protection structure 412 and the first connection portion 31, may be disposed on a same straight line along the first stretching direction X. In this way, it may be possible to effectively prevent the second protection structure 412 from tending to twist in a case where the display panel 100 is stretched or compressed in the first stretching direction X. Similarly, the first extension portion 23, the second extension portion 42, and the third extension portion 43 may be arranged along the second stretching direction Y and may be disposed on the same second straight line L2, such that a connection position between the first side 21 extending along the first stretching direction X and the connection bridge 30, i.e., extending along the second stretching direction Y and the second connection portion 32, and a connection position between the first protection structure 411 and the connection bridge 30, i.e., between the second protection structure 412 and the second connection portion 32, may be disposed on a same straight line along the second stretching direction Y. In this way, it may be possible to effectively prevent the first protection structure 411 from tending to twist in a case where the display panel 100 is stretched or compressed in the second stretching direction Y. With the above-mentioned arrangement, it may be possible to enable the display panel 100 to remain relatively flat during stretching or compression, so as to reduce deformation of a displayed image and reducing the impact on the display effect of the display panel 100 during stretching or compression.

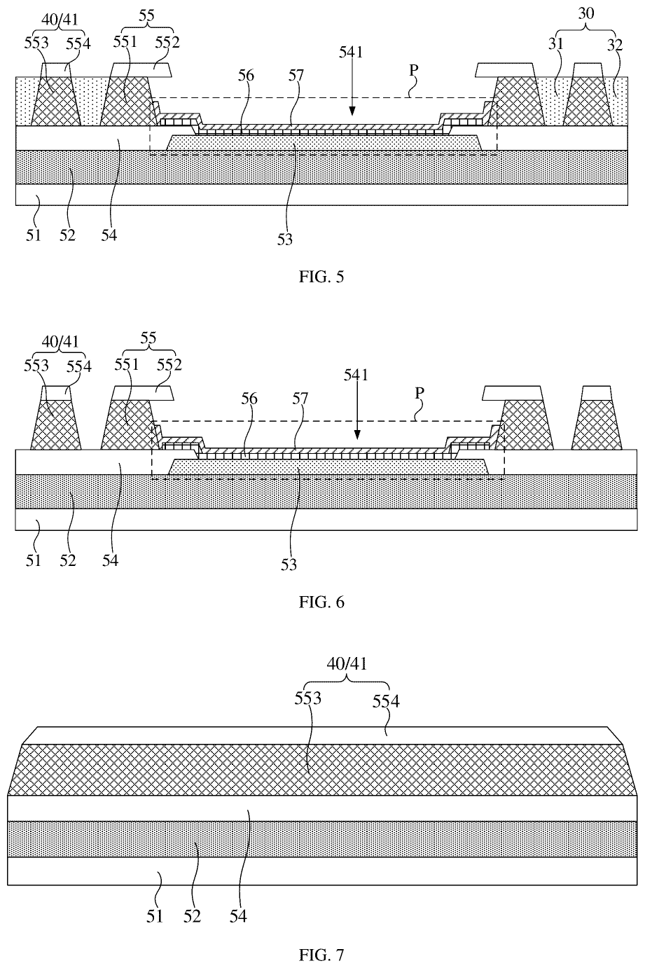

As shown in FIGS. 5-7, FIG. 5 is a cross-sectional structural schematic view of a display panel along a direction of line A-A in FIG. 4 according to some embodiments of the present disclosure. FIG. 6 is a cross-sectional structural schematic view of a display panel along a direction of line B-B in FIG. 4 according to some embodiments of the present disclosure. FIG. 7 is a cross-sectional structural schematic view of a display panel along a direction of line C-C in FIG. 4 according to some embodiments of the present disclosure. In the embodiments of the present disclosure, the corresponding one of the pixel islands 20 may include a driving layer 51, a planarization layer 52, an anode electrode 53, a pixel defining layer 54, and a conductive isolation structure stacked in sequence.

In some embodiments, multiple pixel openings 541 may be defined on the pixel defining layer 54. The multiple pixel openings 541 and anode electrodes 53 may be arranged in one-to-one correspondence. A corresponding one of anode electrodes may be exposed from a corresponding one of the pixel openings 541. The conductive isolation structure may be disposed at a side of the pixel defining layer 54 away from the driving layer 51 and may be arranged around the corresponding one of the pixel openings 541. A light-emitting layer 56 and a cathode electrode 57 may be stacked in sequence in the corresponding one of the pixel openings 541 to form a sub-pixel P with the corresponding of the anode electrodes 53. The cathode electrode 57 may be in contact with and electrically connected to the conductive isolation structure. The protection unit 40 and the conductive isolation structure may be disposed in a same layer. The first connection portion 31 may be connected to the corresponding one of the protection structures 41 and the conductive isolation structure disposed at an edge of the corresponding one of the pixel islands 20.

It should be noted that the conductive isolation structure disposed at an edge region of the corresponding one of the pixel islands 20 may be the structure of the side of the corresponding one of the pixel islands 20 as mentioned above. That is, a shape of the conductive isolation structure disposed at the edge region of the corresponding one of the pixel islands 20 may be the same as the shape of the side of the corresponding one of the pixel islands 20, and the connection bridge 30 may be connected to the conductive isolation structure disposed at an edge region of the corresponding one of the pixel islands 20 and the protection unit 40 disposed around the corresponding one of the pixel islands 20. In some embodiments, the connection bridge 30 may be a signal wiring with a bent/curved distribution and having good deformation capability. The signal wiring may be a conductive metal wire.

In some embodiments, the conductive isolation structure may include a first conductive portion 551 and a first insulating top 552. The first conductive portion 551 may be disposed at the side of the pixel defining layer 54 away from the driving layer 51 and may be arranged around the corresponding one of the pixel openings 541. The first insulating top 552 may be configured to cover a side of the first conductive portion 551 away from the driving layer 51, and configured to shield the first conductive portion 551. The first insulating top 552 may extend beyond the first conductive portion 551 in a direction parallel to the pixel defining layer 54. In some embodiments, the cathode electrode 57 may be disposed in the corresponding one of the pixel openings 541, and may be configured to cover the light-emitting layer 56 to form the sub-pixel P. At the same time, the cathode electrode 57 may be in contact with and electrically connected to the first conductive portion 551, such that cathode electrodes 57 of adjacent sub-pixels P may be electrically connected to each other through the first conductive portion 551 to form a positive electrode. Therefore, it may be possible to facilitate the transmission of cathode signals, so as to prevents display irregularities caused by potential differences among the cathode electrodes 57 of each sub-pixel P in the corresponding one of the pixel islands 20. The side of the first conductive portion 551 away from the driving layer 51 may be covered by the first insulating top 552, the first conductive portion 551 may be shielded by the first insulating top 552, and the first insulating top 552 may extend beyond the first conductive portion 551 in the direction parallel to the pixel defining layer 54, so as to form an overhanging structure, and thus the first insulating top 552 may play the same role as a mask during a process of evaporating the light-emitting material to form the light-emitting layer 56. Therefore, the mask may be replaced, and the evaporation of the light-emitting layer 56 may be realized without a mask, such that it may be possible to effectively improve a pixel aperture ratio and reduce production costs.

In some embodiments, the protection structure 41 may have a film structure similar to that of the conductive isolation structure. The protection structure 41 may include a second conductive portion 553 and a second insulating top 554. The second conductive portion 553 and the first conductive portion 551 may be disposed in a same layer and arranged at intervals. The second insulating top 554 may be disposed at a side of the second conductive portion 553 away from the pixel defining layer 54. With the above arrangement, when the display panel 100 is manufactured, the protection structure 41 may be manufactured together with the conductive isolation structure during a process of manufacturing the conductive isolation structure without adding a special process. In some embodiments, each of a material of the first conductive portion 551 and a material of the second conductive portion 553 may be a metal material with good conductivity. In some embodiments, each of a material of the first insulating top 552 and a material of the second insulating top 554 may be an inorganic insulating material, such that it may be possible to enable the protection structure 41 to have good conductivity and anti-deformation capability.

In some embodiments, the first connection portion 31 may be connected to the first conductive portion 551 and the second conductive portion 553 adjacent to the first conductive portion 551. The second connection portion 32 may be connected to two adjacent second conductive portions 553. The two adjacent second conductive portions 553 and adjacent two of the pixel islands 20 may be arranged in one-to-one correspondence. Therefore, the cathode signals may be transmitted across an entire surface (such as the entire display panel) through the connection bridge 30 and the protection unit 40.

In some embodiments, as shown in FIG. 5, a side of the first insulating top 552 close to the corresponding one of the pixel openings 541 may extend beyond the first conductive portion 551 in a direction parallel to the pixel defining layer. A side of the first insulating top 552 away from the corresponding one of the pixel openings 541 may be not protruded from the first conductive portion 551. In some embodiments, the side of the first insulating top 552 close to the corresponding one of the pixel openings 541 may extend beyond the first conductive portion 551 in the direction parallel to the pixel defining layer, such that an overhanging structure may be formed for evaporating to form the light-emitting layer 56, thereby supporting mask-less evaporation. The side of the first insulating top 552 away from the corresponding one of the pixel openings 541 may be not protruded from the first conductive portion 551, such that it may be possible to prevent the first insulating top layer 552 from shielding a region of the first conductive portion 551 close to a side of the second conductive portion 553, thereby reducing interference on the manufacturing of the first connection portion 31.

As shown in FIGS. 5 and 7, a projection of the second insulating top 554 on the second conductive portion 553 does not exceed the second conductive portion 553, i.e., the projection of the second insulating top 554 on the second conductive portion 553 may fall within a region of the second conductive portion 553. That is, the second insulating top 554 may be not protruded from the second conductive portion 553 in the direction parallel to the pixel defining layer 54, such that it may be possible to prevent the second insulating top 554 from shielding a region of the second conductive portion 553 close to the side of the corresponding one of the pixel islands 20 and a region of the second conductive portion 553 away from the side of the corresponding one of the pixel islands 20. In this way, it may be possible to reducing interference on the manufacturing of the first connection portion 31 and the second connection portion 32 due to shielding.

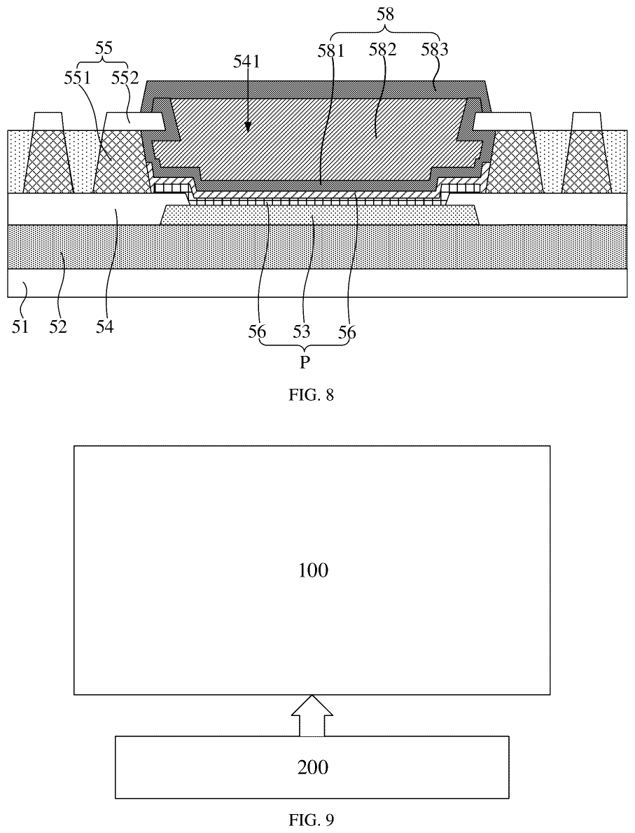

As shown in FIG. 8, FIG. 8 is a cross-sectional structural schematic view of a display panel along a direction of line A-A in FIG. 4 according to another embodiment of the present disclosure. In the embodiments of the present disclosure, the corresponding one of the pixel islands 20 may further include an encapsulation structure 58. The encapsulation structure 58 may be disposed in the corresponding one of the pixel openings 541 and configured to encapsulate and protect the sub-pixel P, so as to prevent a structure of the sub-pixel P from being damaged, and further prevent external water and oxygen from invading and damaging the light-emitting layer 56, thereby extending the service life of the sub-pixel P.

In some embodiments, the encapsulation structure 58 may include a first encapsulation layer 581, a second encapsulation layer 582, and a third encapsulation layer 583 arranged in a stacking manner. In some embodiments, each of a material of the first encapsulation layer 581 and a material of the third encapsulation layer 583 may be an inorganic insulating material such as oxides or nitrides, such as aluminum oxide (Al₂O₃), silicon oxide (SiO₂), SiNₓ inorganic materials (x is a non-zero natural number), so as to block water and oxygen, thereby improving mechanical strength. The first encapsulation layer 581 may be configured to cover a surface of the cathode electrode 57 and may be extended into a side surface of the first insulating top 552 away from the pixel defining layer 54. A material of the second encapsulation layer 582 may be an organic insulating material, such as polyimide (PI), polyethylene terephthalate (PET), and other materials. The second encapsulation layer 582 may be filled in the corresponding one of the pixel openings 541 and configured to planarize the corresponding one of the pixel openings 541. The second encapsulation layer 582 may further be configured to provide buffering stress, so as to improve the flexibility of the display panel 100. The third encapsulation layer 583 may be disposed at a side of the second encapsulation layer 582 away from the first encapsulation layer 581. The third encapsulation layer 583 may be configured to cover the first encapsulation layer 581 and the second encapsulation layer 582, so as to further enhance the ability to block water and oxygen.

As shown in FIG. 9, FIG. 9 is a structural schematic diagram of a display device according to some embodiments of the present disclosure. A display device may be provided in the embodiments of the present disclosure. The display device may include a display panel 100 and a control circuit board 200. In some embodiments, the display panel 100 may be the display panel 100 described in the above-mentioned embodiments, and may have the same/similar structure and function as the display panel 100 described in the above-mentioned embodiments and may achieve the same technical effects. For details, reference may be made to the above detailed description, which is not repeated herein. The control circuit board 200 may be electrically connected to the display panel 100. In some embodiments, the control circuit board 200 may be electrically connected to a driving substrate, and may be configured to control the display panel 100, such that it may be possible to enable the display panel 100 to display a corresponding image according to a corresponding control method.

The display device may have good stretchable deformation performance, and may better protect the structural reliability of the corresponding one of the pixel islands 20 during stretching deformation, so as to improve the anti-deformation capability of the pixel islands 20, and reduce an occurrence of poor display effect caused by the twisting deformation or structural damage of the corresponding one of the pixel islands 20. In some embodiments, the display device may be an electronic device with a display function, such as a mobile phone, a tablet computer, a laptop computer, an electronic paper, a television, a vehicle-mounted display screen, and the like.

Different from the related art, the technical effects of some embodiments of the present disclosure may be as follows. A display panel and a display device may be provided by some embodiments of the present disclosure. The display panel includes multiple pixel islands and a connection bridge. The connection bridge may be stretchably connected between adjacent two of the pixel islands to perform signal transmission and implement image display. The display panel further includes a protection unit disposed around a corresponding one of the pixel islands, so as to generate a resistance to prevent stretching deformation in a case where the display panel is stretched, such that the protection unit has good anti-deformation capability. In this way, it may be possible to effectively reduce the influence of the stress generated by the stretching deformation on the corresponding one of the pixel islands, such that it may be possible to prevent the corresponding one of the pixel islands from being damaged by the deformation stress, thereby improving the anti-deformation capability of the pixel islands. At the same time, the protection unit is spaced apart from the corresponding one of the pixel islands, the first connection portion of the connection bridge is connected to the corresponding one of the pixel islands and the protection unit, and the second connection portion is connected to two adjacent protection units, so as to realize the connection between the multiple pixel islands. When the display panel is stretched, it may be possible to protect the corresponding one of the pixel islands to maintain/remain structural integrity under an external stretching force, and it may also be possible to ensure good stretchability between the corresponding one of the pixel islands and the protection unit disposed in a periphery of the pixel islands, such that it may be possible to enable the display panel to maintain good deformation capability. In addition, the protection unit is conductive, such that the first connection portion is electrically connected to the second connection portion through the protection unit, thereby implementing signal connection and signal transmission.

The above shows only embodiments of the present disclosure and does not limit the scope of the present disclosure. Any equivalent structure or equivalent process transformation performed based on the specification and accompanying drawings of the present disclosure, directly or indirectly applied in other related fields, shall be equivalently covered by the present disclosure.

1. A display panel, comprising:
a plurality of pixel islands, each pixel island comprising at least one sub-pixel; and
a connection bridge, stretchably connected between adjacent two of the pixel islands;
wherein the display panel further comprises a protection unit disposed around a corresponding one of the pixel islands, and the protection unit is spaced apart from the corresponding one of the pixel islands;
the protection unit is configured to generate a resistance to prevent stretching deformation in a case where the display panel is stretched;
the connection bridge comprises a first connection portion and a second connection portion, the first connection portion is connected to the corresponding one of the pixel islands and the protection unit, the second connection portion is connected to two adjacent protection units, and the protection unit is conductive.

2. The display panel according to claim 1, wherein the protection unit is disconnected at a position corresponding to a corner of the corresponding one of the pixel islands, and a plurality of protection structures are formed by the protection unit; and
a corresponding one of the protection structures is parallel to a side of the corresponding one of the pixel islands, and a length of an orthographic projection of the corresponding one of the protection structures on the side of the corresponding one of the pixel islands is less than a length of the side of the corresponding one of the pixel islands.

3. The display panel according to claim 2, wherein an angle between adjacent sides of the corresponding one of the pixel islands is a chamfer.

4. The display panel according to claim 2, wherein each side of the corresponding one of the pixel islands comprises a first extension portion, a side of the protection structure facing the corresponding one of the pixel islands comprises a second extension portion, and a side of the protection structure away from the corresponding one of the pixel islands comprises a third extension portion; and
the first connection portion is connected to a corresponding first extension portion and a corresponding second extension portion, and the second connection portion is connected to two adjacent corresponding third extension portions.

5. The display panel according to claim 4, wherein the display panel at least comprises a first stretching direction and a second stretching direction intersecting each other;
the first extension portion, the second extension portion, and the third extension portion arranged along the first stretching direction are disposed on a same first straight line, and the first straight line is parallel to the first stretching direction; and
the first extension portion, the second extension portion, and the third extension portion arranged along the second stretching direction are disposed on a same second straight line, and the second straight line is parallel to the second stretching direction.

6. The display panel according to claim 2, wherein a shape of a corresponding one of the pixel islands is rectangular, square, rhombic, or polygonal, and the plurality of protection structures and sides of the corresponding one of the pixel islands are arranged in one-to-one correspondence; or
wherein the sides of the corresponding one of the pixel islands comprise a curved side, and the corresponding one of the protection structures is a curved protection structure corresponding to the curved side.

7. The display panel according to claim 2, wherein the corresponding one of the pixel islands comprises a driving layer, a planarization layer, an anode electrode, a pixel defining layer, and a conductive isolation structure stacked in sequence;
a plurality of pixel openings are defined on the pixel defining layer, the plurality of pixel openings and anode electrodes are arranged in one-to-one correspondence, and a corresponding one of the anode electrodes is exposed from a corresponding one of the pixel openings;
the conductive isolation structure is disposed at a side of the pixel defining layer away from the driving layer and is arranged around the corresponding one of the pixel openings;
a light-emitting layer and a cathode electrode are stacked in sequence in the corresponding one of the pixel openings to form the sub-pixel with the corresponding one of the anode electrodes;
the cathode electrode is in contact with and electrically connected to the conductive isolation structure; and
the protection unit and the conductive isolation structure are disposed in a same layer, and the first connection portion is connected to the corresponding one of the protection structures and the conductive isolation structure disposed at an edge of the corresponding one of the pixel islands.

8. The display panel according to claim 7, wherein the conductive isolation structure comprises a first conductive portion and a first insulating top, the first conductive portion is disposed at a side of the pixel defining layer away from the driving layer and arranged around the corresponding one of the pixel openings;
the first insulating top is configured to cover a side of the first conductive portion away from the driving layer, and is configured to shield the first conductive portion, and the first insulating top extends beyond the first conductive portion in a direction parallel to the pixel defining layer;
the protection structure comprises a second conductive portion and a second insulating top, the second conductive portion and the first conductive portion are disposed in a same layer and arranged at intervals, and the second insulating top is disposed at a side of the second conductive portion away from the pixel defining layer; and
the first connection portion is connected to the first conductive portion and the second conductive portion adjacent to the first conductive portion, the second connection portion is connected to two adjacent second conductive portions, and the two adjacent second conductive portions and the adjacent two of the pixel islands are arranged in one-to-one correspondence.

9. The display panel according to claim 8, wherein a side of the first insulating top close to the corresponding one of the pixel openings extends beyond the first conductive portion in a direction parallel to the pixel defining layer, and a side of the first insulating top away from the corresponding one of the pixel openings is not protruded from the first conductive portion; and
a projection of the second insulating top on the second conductive portion does not exceed the second conductive portion.

10. The display panel according to claim 1, wherein an end of the first connection portion is connected to an outer side of the corresponding one of the pixel islands, and another end of the first connection portion is connected to a side of the protection unit close to the corresponding one of the pixel islands;
an end of the second connection portion is connected to a side of one of the two adjacent protection units opposite to the corresponding one of the pixel islands, and another end of the second connection portion is connected to a side of another one of the two adjacent protection units opposite to another corresponding one of the pixel islands.

11. The display panel according to claim 5, wherein the protection unit comprises a first protection structure extending along the first stretching direction and a second protection structure extending along the second stretching direction;
in a case where the corresponding one of the pixel islands is stretched, compressed, or bent in the first stretching direction, the first protection structure is configured to generate a resistance opposite to the first stretching direction; and
in a case where the corresponding one of the pixel islands is stretched, compressed, or bent in the second stretching direction, the second protection structure is configured to generate a resistance opposite to the second stretching direction.

12. The display panel according to claim 11, wherein the corresponding one of the pixel islands comprises four sides, two sides extending along the first stretching direction are first sides, and other two sides extending along the second stretching direction are second sides;
the first protection structure is parallel to a corresponding one of first sides; and
the second protection structure is parallel to a corresponding one of second sides.

13. The display panel according to claim 12, wherein a projection of the first protection structure on the corresponding one of first sides falls within a region of the corresponding one of first sides;
the projection of the second protection structure on the corresponding one of second sides falls within a region of the corresponding one of second sides.

14. The display panel according to claim 8, wherein the corresponding one of the pixel islands further comprises an encapsulation structure disposed in the corresponding one of the pixel openings, and the encapsulation structure is configured to encapsulate and protect the sub-pixel.

15. The display panel according to claim 14, wherein the encapsulation structure comprises a first encapsulation layer, a second encapsulation layer, and a third encapsulation layer arranged in a stacking manner;
the first encapsulation layer is configured to cover a surface of the cathode electrode and is extended into a side surface of the first insulating top away from the pixel defining layer;
the second encapsulation layer is filled in the corresponding one of the pixel openings and configured to planarize the corresponding one of the pixel openings; and
the third encapsulation layer is disposed at a side of the second encapsulation layer away from the first encapsulation layer; and the third encapsulation layer is configured to cover the first encapsulation layer and the second encapsulation layer.

16. The display panel according to claim 8, wherein each of a material of the first conductive portion and a material of the second conductive portion is a metal material with good conductivity; and
each of a material of the first insulating top and a material of the second insulating top is an inorganic insulating material.

17. The display panel according to claim 1, wherein the display panel further comprises a flexible substrate configured to carry the plurality of pixel islands and the connection bridge.

18. The display panel according to claim 1, wherein a spacing with a preset width is provided between the protection unit and the corresponding one of the pixel islands.

19. The display panel according to claim 1, wherein the second connection portion disposed between the two adjacent protection units is a same second connection portion.

20. A display device, comprising:
a display panel; and
a control circuit board, electrically connected to the display panel and configured to control the display panel to display a corresponding image;
wherein the display panel comprises:
a plurality of pixel islands, each pixel island comprising at least one sub-pixel; and
a connection bridge, stretchably connected between adjacent two of the pixel islands;
wherein the display panel further comprises a protection unit disposed around a corresponding one of the pixel islands, and the protection unit is spaced apart from the corresponding one of the pixel islands;
the protection unit is configured to generate a resistance to prevent stretching deformation in a case where the display panel is stretched;
the connection bridge comprises a first connection portion and a second connection portion, the first connection portion is connected to the corresponding one of the pixel islands and the protection unit, the second connection portion is connected to two adjacent protection units, and the protection unit is conductive.
